(19) United States
(12) Patent Application Publication
(10) Pub. No.: US 2026/0221970 A1
(43) Pub. Date: Jul. 30, 2026

(54) SIGNAL TRANSMISSION DEVICE, ELECTRONIC DEVICE PROVIDED WITH SIGNAL TRANSMISSION DEVICE, AND VEHICLE PROVIDED WITH ELECTRONIC DEVICE

(71) Applicant: ROHM CO., LTD., Kyoto-shi (JP)

(72) Inventors: Koki MISHIMA, Kyoto-shi (JP); Daiki YANAGISHIMA, Kyoto-shi (JP)

(21) Appl. No.: 19/573,555

(22) Filed: Mar. 20, 2026

Related U.S. Application Data
(63) Continuation of application No. PCT/JP2024/031028, filed on Aug. 29, 2024.

(30) Foreign Application Priority Data
Sep. 22, 2023 (JP) 2023-158463

(51) Int. Cl. H03K 17/687

(52) U.S. Cl. CPC H03K 17/687

(57) ABSTRACT

A signal transmission device 200X comprises a transmission circuit, a reception circuit configured to output a drive control signal in accordance with a first internal signal and a second internal signal; an insulation circuit; and a driving circuit. The transmission circuit drives at least one of the first internal signal and the second internal signal at a specific period in accordance with an external signal. The reception circuit detects that the period of at least one of the first internal signal and the second internal signal is a specific period and outputs a drive control signal. The driving circuit receives the drive control signal, suspends driving of a driving target switch element, and puts an output node of the driving circuit in a high impedance state.

### CROSS REFERENCE TO RELATED APPLICATIONS

This application is a continuation under 35 U.S.C. § 120 of PCT/JP2024/031028 filed on Aug. 29, 2024, which is incorporated herein by reference, and which claimed priority to Japanese Patent Application No. 2023-158463 filed on Sep. 22, 2023, the entire contents of which are hereby incorporated by reference.

### TECHNICAL FIELD

The invention disclosed herein relates to a signal transmission device, an electronic device provided with the signal transmission device, and a vehicle provided with the electronic device.

### BACKGROUND ART

Conventionally, a signal transmission device that transmits a pulse signal while keeping isolation between input and output has been used for various applications (power supply devices, motor driving devices, etc.).

Patent Document 1 may be mentioned as one example of prior arts related to the above description.

### CITATION LIST

### Patent Literature

Patent Document 1: JP 2017-188903 A

### BRIEF DESCRIPTION OF DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram schematically showing the basic structure of an electronic device on which the signal transmission device of the present disclosure is mounted.

FIG. 11 is a block diagram illustrating the internal structure of a high-impedance signal detection circuit according to a first embodiment.

FIG. 12 is a timing chart showing states of individual signals at a timing when the OUT terminal of the signal transmission device according to the first embodiment switches from a normal state to a high impedance state.

FIG. 13 is a block diagram illustrating the internal structure of a counter circuit.

FIG. 14 is a block diagram illustrating an implemental example of the signal transmission device according to the present disclosure.

### DESCRIPTION OF EMBODIMENTS

### Signal Transmission Device (Basic Configuration)

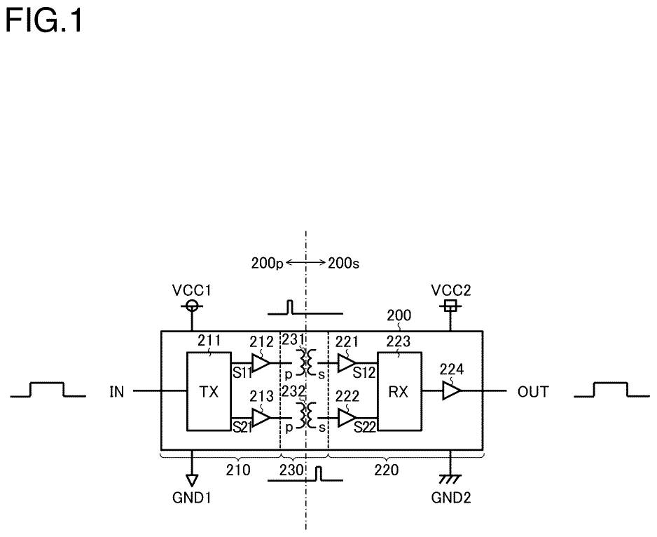

FIG. 1 is a diagram illustrating the basic configuration of a signal transmission device.

The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts), and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

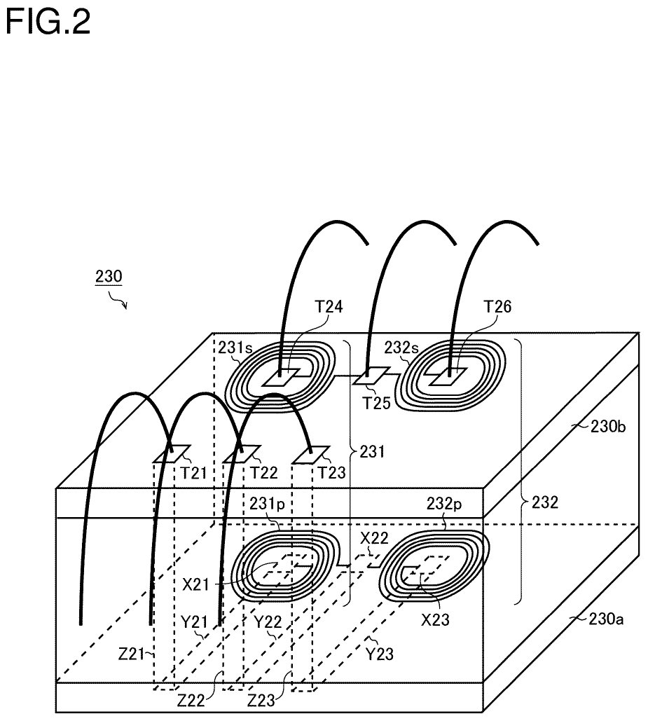

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230, and is DC-isolated from the controller chip 210 by the transformer chip 230.

### Transformer Chip (Two-Channel Type)

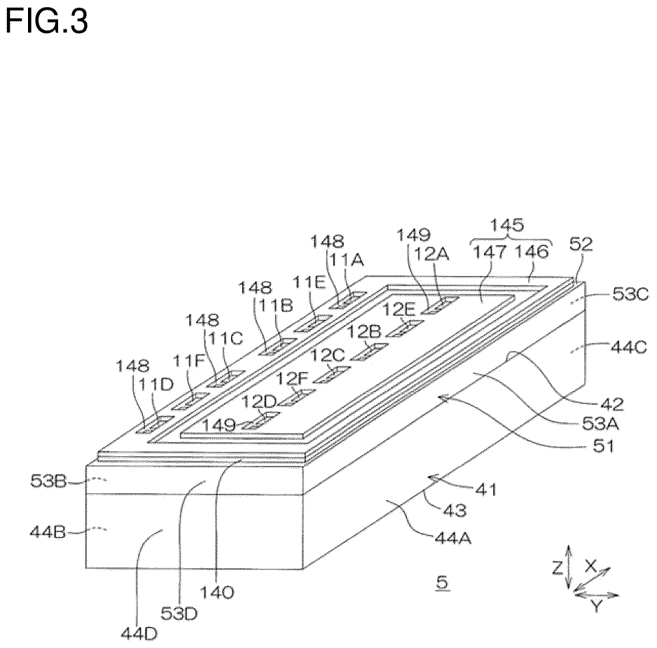

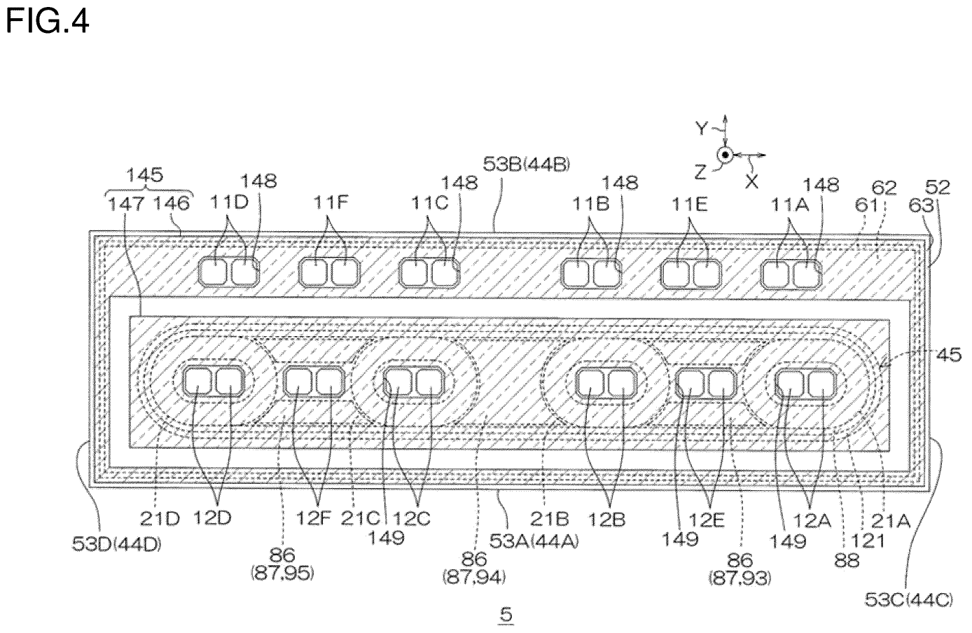

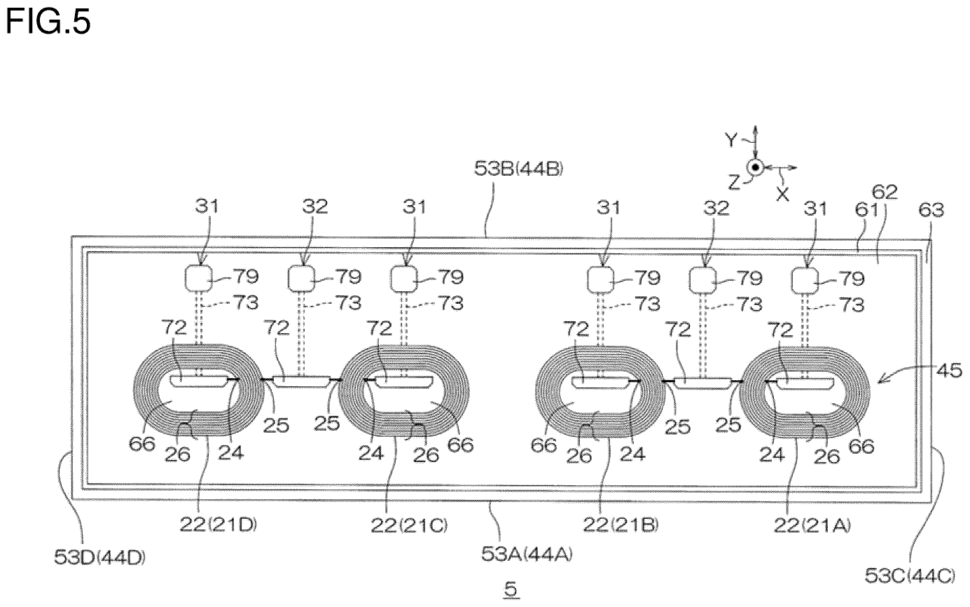

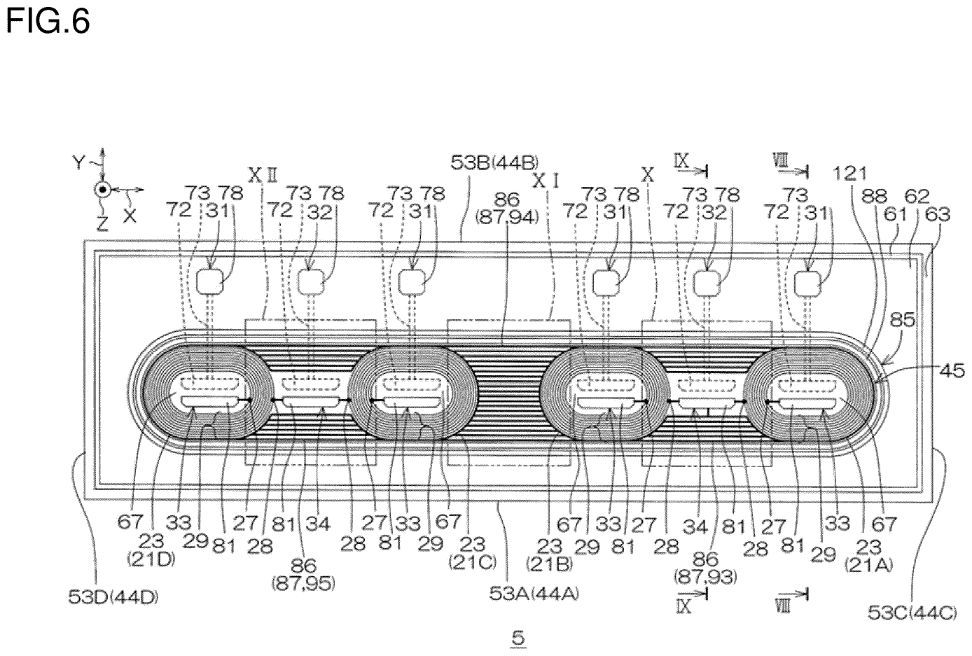

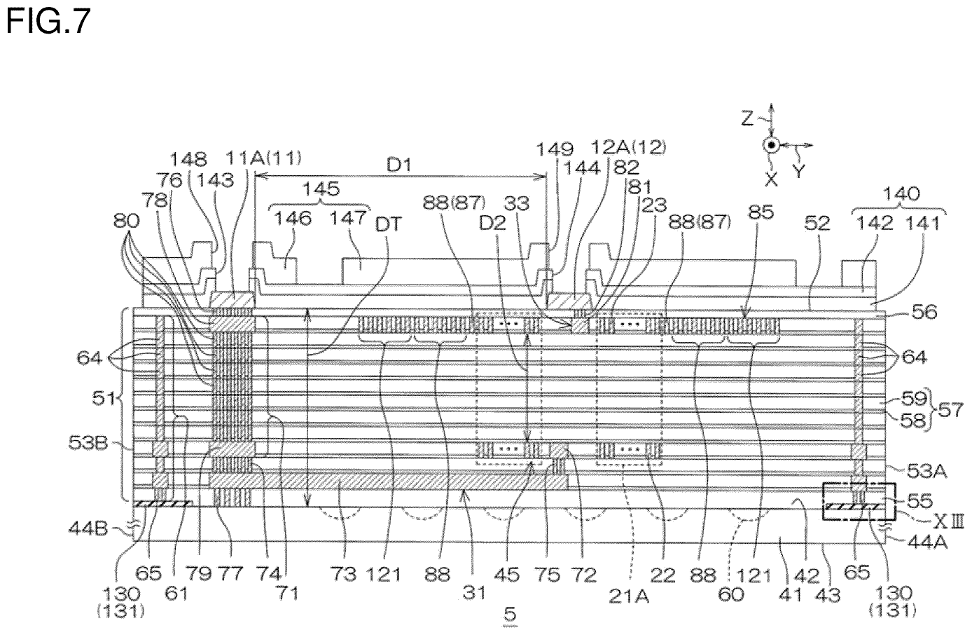

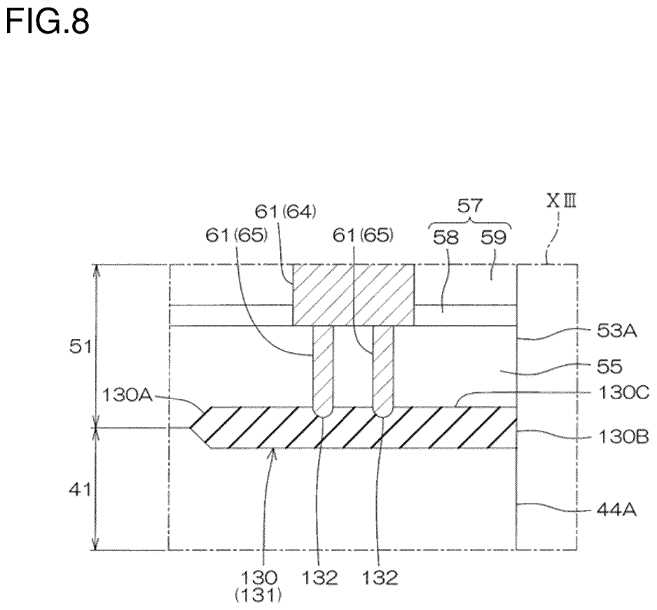

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIGS. 3 to 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41, and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58 and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIGS. 5 to 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIGS. 5 and 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23, and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41, and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73, and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73, and are electrically connected to the semiconductor chip 41 and to the first end part of the lead wiring 73.

Referring to FIGS. 6 and 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIGS. 6 and 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22, and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41, and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring, and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIGS. 5 to 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41, and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62 as seen in a plan view. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41, and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area equal to or larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIGS. 7 and 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41, and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146, and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low-and high-potential terminals 11 and 12, it is possible to suppress unnecessary conduction between the high-potential terminal 12 and the sealing conductor 61. Likewise, in a case where a voltage is applied to the second functional device 60 via the low-and high-potential terminals 11 and 12, it is possible to suppress unnecessary conduction between the low-potential terminal 11 and the sealing conductor 61.

The embodiment described above deals with an example where a second functional device 60 is formed. The second functional device 60 however is not essential and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

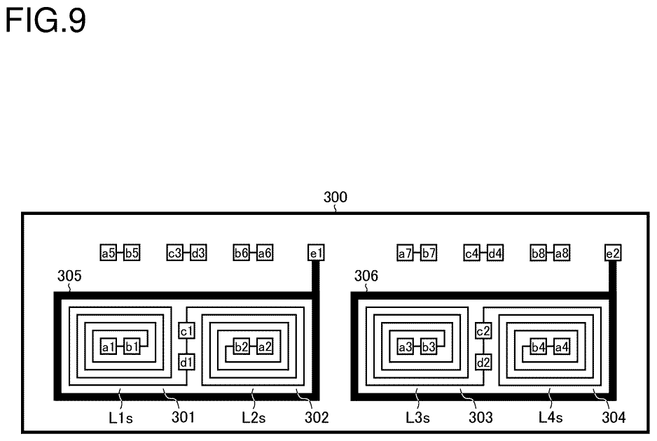

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively, and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are however not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Discussions on Functional Safety

The above-described signal transmission device 200 drives pulsation of the output pulse signal OUT between high and low levels to turn on/off the switching device provided in the secondary circuit system 200s. In this context, there is a desire for driving the switching device of the secondary circuit system 200s, without depending on the signal transmission device 200, by another route. An example of such a desire is that upon occurrence of any malfunction in the signal transmission device 200, halting the operation of the signal transmission device 200 is desired from a functional safety's point of view. However, halting the operation of the signal transmission device 200 would involve a halt of the driving of the switching device of the secondary circuit system 200s. As a result, there may arise influences on operations of above-described devices (power supply device of on-vehicle equipment, motor driving device, etc.) on which the signal transmission device 200 is mounted.

In view of such problems described above, a signal transmission device 200X of this disclosure is enabled to drive the switching device (later-described switching device SW), which is a driving target provided in the secondary circuit system 200s, by another route other than the signal transmission device 200X. Therefore, it becomes possible to halt the operation of the signal transmission device 200X while suppressing influences on functions of devices on which the signal transmission device 200X is mounted. Hereinbelow, detailed descriptions will be given on the signal transmission device 200X according to the present disclosure, as well as an electronic device 400 on which the signal transmission device 200X is mounted.

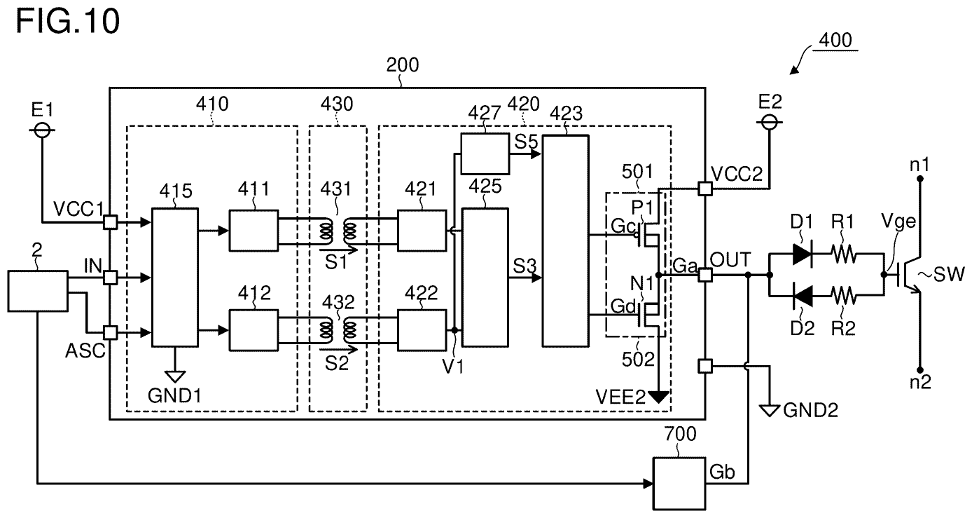

FIG. 10 is a diagram showing the basic structure of an electronic device 400 on which the signal transmission device 200X of the disclosure is mounted. The electronic device 400 of this configuration example is one type of motor driving device that transforms DC power, which is supplied from an unshown on-vehicle battery, into AC power to drive a motor M (see FIG. 16 described later).

As shown in FIG. 10, the electronic device 400 includes an ECU (Electronic Control Unit) 2, the signal transmission device 200X, an external driver circuit 700, and a plurality of discrete components (switching device SW, diodes D1, D2, and resistors R1, R2).

The ECU 2 is a means to centralizedly perform electrical control over a motor driving device as well as a vehicle on which the motor driving device is mounted. The ECU 2 feeds an input signal IN and a high-impedance input signal ASC into the signal transmission device 200X to control the signal transmission device 200X. The ECU 2, for driving execution, switches over the signal level of the input signal IN between high level (on VCC1 base) and low level (on GND1 base). The ECU 2, also for driving execution, switches over the signal level of the high-impedance input signal ASC between high level (on VCC1 base) and low level (on GND1 base).

The signal transmission device 200X is a semiconductor integrated circuit device. The signal transmission device 200X is so configured as to, while keeping isolation between a primary circuit system (VCC1-GND1 system) and a secondary circuit system (VCC2-VEE2 system), transmit a gate drive signal from the primary circuit system to the secondary circuit system.

The signal transmission device 200X, as a means intended to establish electrical connections with the external of the device, includes a plurality of external terminals (in this figure, VCC1 terminal, IN terminal, ASC terminal, VCC2 terminal, and OUT terminal).

The VCC1 terminal is a power supply terminal for the primary circuit system. The primary circuit system receives power supply from a voltage source E1 via the VCC1 terminal. The VCC2 terminal is a power supply terminal for the secondary circuit system. The secondary circuit system receives power supply from a voltage source E2 via the VCC2 terminal.

The IN terminal is a control input terminal. The IN terminal is connected to the ECU 2. The IN terminal receives input of an input signal IN from the ECU 2.

The ASC terminal is a control input terminal other than the IN terminal. The ASC terminal is connected to the ECU 2. The ASC terminal receives input of a high-impedance input signal ASC from the ECU 2.

The OUT terminal (output node) is an output terminal that outputs a drive control signal Ga. The drive control signal Ga is a control signal intended to drive a switching device SW (drive-targeted switching device). The OUT terminal is connected to the gate terminal of the switching device SW via the resistors R1, R2 and the diodes D1, D2.

Preferably applied as the switching device SW are power semiconductor devices operable at high frequencies such as IGBT, power MOSFET (Metal Oxide Semiconductor Field Effect Transistor), SiC-MOSFET (Silicon Carbide-Metal Oxide Semiconductor FET), SiC-SIT (SiC-Static Induction Transistor), and GaN-MOSFET (Gallium Nitride-MOSFET). In the electronic device 400, as shown in FIG. 10, an IGBT is used as the switching device SW.

A gate signal Vge is inputted to a gate end of the switching device SW. The gate signal Vge is variable depending on the drive control signals Ga, Gb. That is, the switching device SW is drive-controlled by the drive control signal Ga outputted from the signal transmission device 200X or the drive control signal Gb outputted from a later-described external driver circuit 700.

More specifically, when the gate signal Vge is at high level (exceeding a threshold voltage of the switching device SW), the switching device SW is turned on. When the gate signal Vge is at low level (not exceeding the threshold value of the switching device SW), the switching device SW is turned off.

The collector of the switching device SW is connected to a node n1. The emitter of the switching device SW is connected to a node n2. Concrete examples of the nodes n1 and n2 will be described later.

The external driver circuit 700 is connected to the ECU 2 and the OUT terminal. The external driver circuit 700 outputs the drive control signal Gb in response to a control signal inputted from the ECU 2.

### Internal Configuration of Signal Transmission Device 200X

Next, the internal configuration of the signal transmission device 200X is described in detail. The signal transmission device 200X contains, as sealed in one package, a first semiconductor chip 410, a second semiconductor chip 420, and a third semiconductor chip 430.

The first semiconductor chip 410 is equivalent to the foregoing primary circuit system 200p. The first semiconductor chip 410 is a controller chip in which controllers capable of generating various signals are integrated together. The first semiconductor chip 410 is driven by being supplied with the supply voltage VCC1 from the voltage source E1. The first semiconductor chip 410 generates a first internal signal S1 and a second internal signal S2 on a basis of the input signal IN.

The second semiconductor chip 420 is equivalent to the foregoing secondary circuit system 200s. The second semiconductor chip 420 is a driver chip in which drivers for drive control of the switching device SW are integrated together. The second semiconductor chip 420 is driven by being supplied with the supply voltage VCC2 from the voltage source E2. The first internal signal S1 and the second internal signal S2 are inputted from the first semiconductor chip 410 via the third semiconductor chip 430 to the second semiconductor chip 420. The second semiconductor chip 420 generates the drive control signal Ga on a basis of the first internal signal S1 and the second internal signal S2.

The third semiconductor chip 430 is a transformer chip in which a plurality of transformers (first transformer 431, second transformer 432, third transformer 433, fourth transformer 434, fifth transformer 435, and sixth transformer 436 according to FIG. 10) are integrated together. The third semiconductor chip 430 transmits the first internal signal S1 and the second internal signal S2 while keeping DC-base isolation between the first semiconductor chip 410 and the second semiconductor chip 420.

The first semiconductor chip 410 includes a logic circuit 415, a first transmission circuit 411, and a second transmission circuit 412.

The logic circuit 415, upon receiving the input signal IN and the high-impedance input signal ASC inputted from the ECU 2, generates the first internal signal S1 and the second internal signal S2, inputting the signals to the first transmission circuit 411 and the second transmission circuit 412, respectively.

The first transmission circuit 411 transmits the first internal signal S1, which is inputted from the logic circuit 415, to a first reception circuit 421 via the first transformer 431.

The second transmission circuit 412 transmits the second internal signal S2, which is inputted from the logic circuit 415, to a second reception circuit 422 via the second transformer 432.

The second semiconductor chip 420 includes the first reception circuit 421, the second reception circuit 422, a logic circuit 425, a high-impedance signal detection circuit 427, a driver circuit 423, and an output circuit 501.

The first reception circuit 421 inputs the first internal signal S1, which has been received from the first transmission circuit 411 via the first transformer 431, to the logic circuit 425.

The second reception circuit 422 inputs the second internal signal S2, which has been received from the second transmission circuit 412 via the second transformer 432, to the logic circuit 425.

The logic circuit 425, based on the inputted first internal signal S1 and second internal signal S2, generates a driver control signal S3 (first control signal) and inputs it to the driver circuit 423.

The high-impedance signal detection circuit 427, in response to an output V1 of the second reception circuit 422, generates a high-impedance control signal S5 (second control signal). A voltage value of the output V1 is equivalent to a signal level of the second internal signal S2. The generation of the high-impedance control signal S5 will be detailed later.

The driver circuit 423, based on the inputted driver control signal S3 and high-impedance control signal S5, generates drive signals Gc, Gd. The driver circuit 423 controls the output circuit 501 by the drive signals Gc, Gd.

The output circuit 501 includes a transistor P1 (output switching device), and a transistor N1 (output switching device). The transistor P1 is a P-channel MOSFET. The transistor N1 is an N-channel MOSFET.

The source of the transistor P1 is connected to the VCC2 terminal. Both drains of the transistor P1 and the transistor N1 are connected to the OUT terminal. The source of the transistor N1 is connected to a connection end of VEE2. Both gates of the transistors P1 and N1 are connected to the driver circuit 423.

The drive signal Gc is inputted to a gate end of the transistor P1. The transistor P1 is on/off controlled by the drive signal Gc. The drive signal Gd is inputted to a gate end of the transistor N1. The transistor N1 is on/off controlled by the drive signal Gd. In addition, in a normal state (a state other than a later-described high-impedance state), the drive control signal Ga of high level (on VCC2 base) or low level (on VEE2 base) is outputted from the OUT terminal in response to on/off state of the transistors P1 and N1.

Next, operation of the signal transmission device 200X is described. First, on/off control of the switching device SW in a normal state (a case where the OUT terminal is kept from the high-impedance state) is explained.

In this case, the ECU 2 sets the high-impedance input signal ASC to low level. When the high-impedance input signal ASC of low level is inputted to the ASC terminal, the logic circuit 415 generates periodic pulses for the first internal signal S1 and the second internal signal S2 in response to the input signal IN. A pulse period of the first internal signal S1 and the second internal signal S2 in this case (a case where the high-impedance input signal ASC is at low level) is regarded as a reference period.

The high-impedance signal detection circuit 427 monitors the output V1 to detect the pulse period of the second internal signal S2. When the second internal signal S2 is pulse-driven at the reference period, the high-impedance signal detection circuit 427 sets the high-impedance control signal S5 to low level (third logic level).

When the high-impedance control signal S5 is at low level, the driver circuit 423 generates the drive signals Gc, Gd based on the driver control signal S3 to exert on/off control over the transistors P1, N1. As a result, the switching device SW is on/off-controlled in response to the IN signal.

Next, on/off control over the switching device SW involved in setting of the OUT terminal to the high-impedance state is described. In this case, the ECU 2 sets the high-impedance input signal ASC to high level. When the high-impedance input signal ASC of high level is inputted to the ASC terminal, the logic circuit 415 pulse-drives the second internal signal S2 at a specific period other than the reference period. More specifically, the logic circuit 415 detects a rising edge of the high-impedance input signal ASC to start a pulse drive of the second internal signal S2 at the specific period.

For example, with the reference period set to 100 ns, the specific period becomes different from 100 ns. In this case, the specific period is set to 50 ns.

Upon detecting that the second internal signal S2 is being pulse-driven at the specific period, the high-impedance signal detection circuit 427 raises the high-impedance control signal S5 to high level (fourth logic level).

When the high-impedance control signal S5 is at high level, the driver circuit 423 sets the OUT terminal to a high-impedance state. More specifically, the driver circuit 423 generates the drive signals Gc, Gd so that the transistors P1, N1 are turned off, respectively. In this state, the switching device SW is drive-controlled by the drive control signal Gb.

### High-Impedance Signal Detection Circuit 427

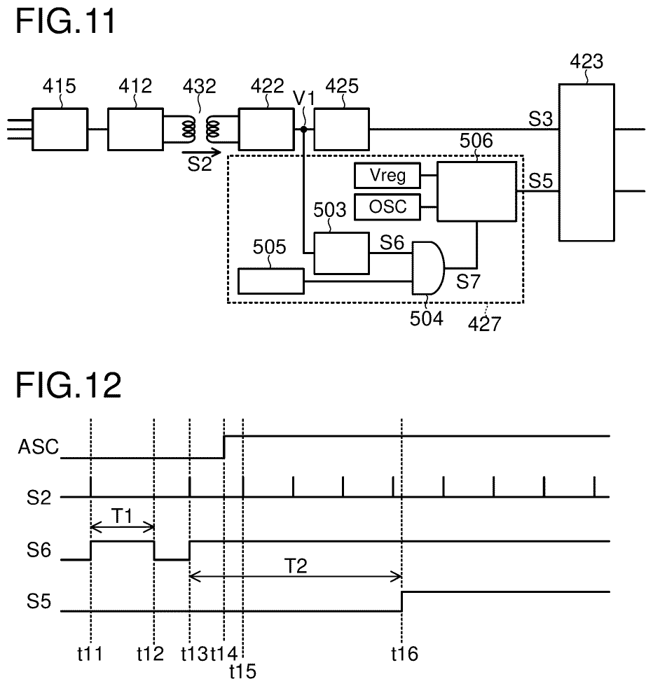

Next, the configuration of the high-impedance signal detection circuit 427 is described in detail. FIG. 11 is a block diagram illustrating the internal structure of the high-impedance signal detection circuit 427 according to the first embodiment. As shown in FIG. 11, the high-impedance signal detection circuit 427 includes a timer circuit 503, an AND gate 504, a UVLO (Under Voltage Lock Out) circuit 505, a counter circuit 506, and an oscillator OSC.

The timer circuit 503 generates a timer drive signal S6 responsive to the pulse period of the second internal signal S2. Detailed description thereof is as follows. The timer circuit 503 monitors the output V1 to detect a pulse of the second internal signal S2. When detecting the pulse of the second internal signal S2, the timer circuit 503 raises the timer drive signal S6 to high level (first logic level). This timing at which the timer drive signal S6 is raised to high level (=a timing at which the pulse of the second internal signal S2 is detected) is herein defined as pulse detection timing (first timing).

In a case where a first set time T1 has elapsed during a time duration from one pulse detection timing until succeeding pulse detection timing, the timer circuit 503 lowers the timer drive signal S6 to low level (second logic level). The first set time T1 is set to a time duration shorter than the above-described reference period.

That is, with the second internal signal S2 being pulse-driven at the reference period, the timer drive signal S6 is lowered to low level at a timing when the first set time T1 has elapsed since the pulse detection timing. Conversely, when the second internal signal S2 is being pulse-driven at a period (=specific period) shorter than the reference period, a succeeding pulse detection timing comes up before the first set time T1 elapses since the first timing. Thus, in this case, the timer drive signal S6 is held at high level without falling to low level.

The UVLO circuit 505 and the AND gate 504 constitute an under voltage lock out function. More specifically, the UVLO circuit 505 basically inputs a high-level control signal to the AND gate 504. When the supply voltage has lowered during operation of the electronic device 400 so as to fall below a specified UVLO detection voltage (not shown), the UVLO circuit 505 inputs the low-level control signal to the AND gate 504. In this figure, for explanation's sake, the UVLO circuit 505 is depicted as a constituent element of the high-impedance signal detection circuit 427. However, the UVLO circuit 505 can be understood as one of protective circuits for the second semiconductor chip 420.

While the UVLO circuit 505 keeps outputting a high-level control signal (while the supply voltage exceeds a UVLO detection voltage during operation of the electronic device 400), the AND gate 504 inputs, to the counter circuit 506, an output signal S7 equivalent to a logic level of the timer drive signal S6. While the UVLO circuit 505 keeps outputting a low-level control signal (while the supply voltage falls below a UVLO detection voltage during operation of the electronic device 400), the AND gate 504 outputs a low-level output signal S7 without depending on the timer drive signal S6. In this case, even though the second internal signal S2 keeps pulse-driving at a specific period, yet the high-impedance signal detection circuit 427 does not detect that the second internal signal S2 is pulse-driven at a specific period. Therefore, the driver circuit 423 does not set the OUT terminal to a high-impedance state.

The counter circuit 506 generates a high-impedance control signal S5 responsive to the timer drive signal S6. Detailed description thereof is as follows. The counter circuit 506 detects a time duration for which the timer drive signal S6 has been maintained at one logic level since a switching of the timer drive signal S6 to the one logic level. More specifically, the counter circuit 506 detects a time duration for which the timer drive signal S6 has been maintained at high level since its rising edge.

In other words, the counter circuit 506 detects whether or not the timer drive signal S6 has been switched to low level during a time duration lasting from a timing (second timing) when the timer drive signal S6 is switched to high level until a second set time T2 elapses. The second set time T2 in this case may be set to 160 ns as an example.

Assume that the timer drive signal S6 has been maintained still at high level during a time duration lasting from a timing when the timer drive signal S6 is switched to high level until the second set time T2 elapses. In this case, the counter circuit 506 sets the high-impedance control signal S5 to high level at the timing when the second set time T2 elapses. Assume that the timer drive signal S6 is switched to low level again before the second set time T2 elapses since a timing when the timer drive signal S6 is switched to high level. In this case, the counter circuit 506 sets the high-impedance control signal S5 to low level.

FIG. 12 is a timing chart showing states of individual signals at a timing when the OUT terminal of the signal transmission device 200X according to the first embodiment switches from a normal state to a high impedance state. Shown in FIG. 12 are, in descending order from above, high-impedance input signal ASC, second internal signal S2, timer drive signal S6, and high-impedance control signal S5. With reference to FIG. 12, control of transition to the high-impedance state of the OUT terminal is described below in more detail.

While the high-impedance input signal ASC keeps at low level (during a time duration from time t11 to t14), the logic circuit 415 pulse-drives the second internal signal S2 at the reference period.

First, as the second internal signal S2 has a pulse rising at time t11, the timer drive signal S6 rises to high level. At time t12 when the first set time T1 has elapsed since the time t11, the timer drive signal S6 falls to low level. An interval from time t11 to time t12 is shorter than the second set time T2. Therefore, the high-impedance control signal S5 is unchanged still at low level.

When time t13 comes up with a pulse rising in the second internal signal S2 again, the timer drive signal S6 also rises to high level again.

Thereafter, the high-impedance input signal ASC rises to high level at time t14. Then, the logic circuit 415 starts pulse-driving at the specific period of the second internal signal S2 with a preceding-time detection timing (=time t13) taken as a starting point. When time t15 comes up, the second internal signal S2 has a next pulse rising. An interval between the time t13 and the time t15 equals one period of the specific period.

As described before, the specific period is shorter than the first set time T1. Therefore, the next detection timing (=t15) comes up before the first set time T1 elapses since the time t13. Thus, the timer drive signal S6 is maintained still at high level without falling to low level.

After the time t15 onward, the high-impedance input signal ASC keeps still at high level, so that the second internal signal S2 keeps pulse-driving at the specific period. Then, at time t16 when the second set time T2 has elapsed since the time t15, the high-impedance control signal S5 rises to high level. Upon receiving the high-impedance control signal S5 of high level, the driver circuit 423 turns off the transistors P1, N1 (not shown). As a result, the OUT terminal goes to a high-impedance state.

In addition, after the time t16 and until the high-impedance input signal ASC falls to low level, the switching device SW is drive-controlled by the drive control signal Gb outputted by the external driver circuit 700. Also, although not shown in FIG. 12, the first internal signal S1 keeps pulse-driving at a normal period until time t14. After the time t14 outward, the first internal signal S1 is maintained at low level.

### Configuration of Counter Circuit 506

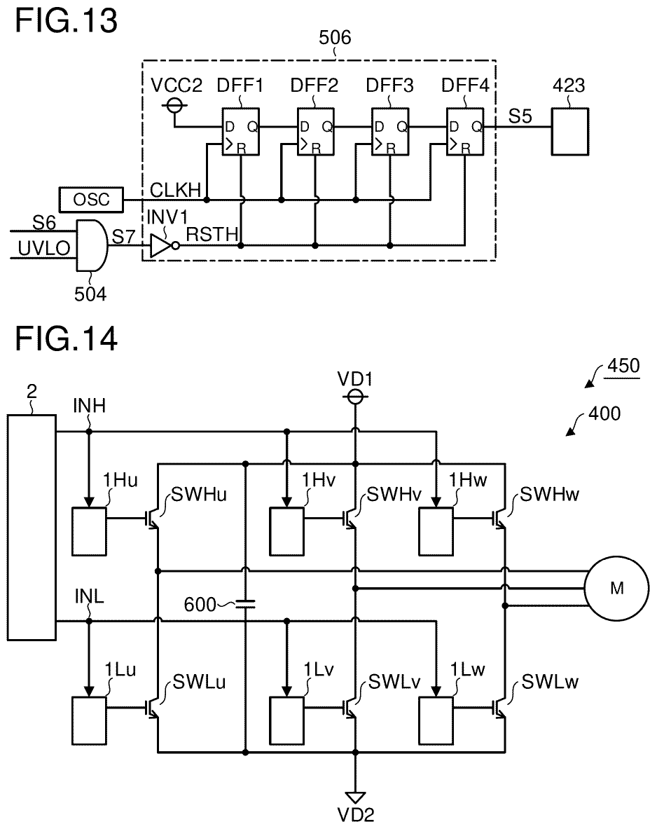

Next, configuration of the counter circuit 506 is described. FIG. 13 is a block diagram illustrating the internal structure of the counter circuit 506. As shown in FIG. 13, the counter circuit 506 includes D flip-flops DFF1 to DFF4, and an inverter INV1. The counter circuit 506 counts number of pulses of a clock signal CLKH generated by the oscillator OSC to generate a set signal (high-impedance control signal S5).

Clock ends of the D flip-flops DFF1 to DFF4 are connected to application ends, respectively, of the clock signal CLKH. A data end (D) of the D flip-flop DFF1 is connected to an application end (=VCC2 terminal) of a high level signal. An output end (Q) of the D flip-flop DFF1 is connected to a data end (D) of the D flip-flop DFF2. An output end (Q) of the D flip-flop DFF2 is connected to a data end (D) of the D flip-flop DFF3. An output end (Q) of the D flip-flop DFF3 is connected to a data end (D) of the D flip-flop DFF4. An output end (Q) of the D flip-flop DFF4 is connected to an input end of the driver circuit 423 as an output end of the set signal S.

Also, reset ends (R) of the D flip-flops DFF1 to DFF4 are connected to application ends, respectively, of a reset signal RSTH. The reset signal RSTH, being a logically inverted signal of the output signal S7, is generated by the inverter INV1. The inverter INV1, upon receiving input of the output signal S7 of the AND gate 504, generates the reset signal RSTH.

The counter circuit 506 having the above-described configuration is configured to count number of pulses of the clock signal CLKH. When the count number has reached a specified value (four in the case of this figure), the high-impedance control signal S5 is raised to high level. In addition, the above-mentioned specified value may be arbitrarily set by changing the number of stages of the D flip-flops.

Also, when the reset signal RSTH falls to low level (i.e., when the output signal S7 rises to high level; in other words, when the timer drive signal S6 rises to high level), the counter circuit 506 is reset, with its count value returned to an initial value (=0).

The above-mentioned second set time T2 can be defined based on the specified value (number of stages of D flip-flops) and the frequency of the clock signal CLKH. In this case, the specified value is set to four, and the frequency of the clock signal CLKH is set to 25.6 MHz. As a result of this, the time in which the count value reaches the specified value is 156 ns.

As described above, the signal transmission device 200X according to this embodiment is enabled to bring the OUT terminal to the high-impedance state. As a result, from outside the signal transmission device 200X (in this case, from the external driver circuit 700), the switching device SW can be drive-controlled by using the drive control signal Gb other than the drive control signal Ga. Accordingly, the switching device SW can be driven without depending on the signal transmission device 200X while influences on functions of the electronic device 400 are suppressed.

Also as described above, the signal transmission device 200X according to the above embodiment is enabled to make a transition to the high-impedance state by pulse-driving the second internal signal S2 at a specific period and then detecting that a pulse period of the second internal signal S2 equals the specific period. That is, there is no need for providing any additional signal transmission route as a route for transmission of control signals involved in setting the OUT terminal to the high-impedance state, except the transmission route of the first internal signal S1 (a route consisting of the first transmission circuit 411, the first transformer 431 and the first reception circuit 421), and the transmission route of the second internal signal S2 (a route consisting of the second transmission circuit 412, the second transformer 432 and the second reception circuit 422). Therefore, the signal transmission device 200X of the above embodiment is enabled to suppress increases in each circuit area of the primary circuit system, the secondary circuit system, and the isolation circuit. Moreover, for a signal transmission device configured by sealing the first semiconductor chip 410, the second semiconductor chip 420, and the third semiconductor chip 430 into one chip like the above-described signal transmission device 200X, it becomes possible to suppress upsizing of the chips.

### Implemental Example of Signal Transmission Device 200X of Present Disclosure

FIG. 14 is a block diagram illustrating an implemental example of the signal transmission device 200X according to the present disclosure. An electronic device 400 on which the signal transmission device 200X of this disclosure is mounted may preferably be used for a vehicle 450, which is an engine vehicle or an electric vehicle. The electronic device 400 may preferably be used as a motor driving device that executes drive control of a motor M mounted on the vehicle 450.

The motor M is a three-phase motor which is rotationally driven in response to three-phase drive voltages U/V/W inputted from half-bridge output stages of the three phases (U phase/ V phase/phase), respectively.

The electronic device 400 includes three insulated gate drivers 1H(u/v/w), three insulated gate drivers 1L(u/v/w), three high-side switching devices SWH(u/v/w), three low-side switching devices SWL(u/v/w), the ECU 2, and a smoothing capacitor 600.

The insulated gate drivers 1H(u/v/w), while keeping isolation between the ECU 2 and the high-side switching devices SWH(u/v/w), generate upper gate drive signals (equivalent to foregoing output signals OUT) in response to upper gate control signals (equivalent to foregoing input signals IN) inputted from the ECU 2 so as to drive the high-side switching devices SWH(u/v/w), respectively.

The insulated gate drivers 1L(u/v/w), while keeping isolation between the ECU 2 and the low-side switching devices SWL(u/v/w), generate lower gate drive signals in response to low-side gate control signals inputted from the ECU 2 so as to drive the low-side switching devices SWL(u/v/w), respectively.

The high-side switching devices SWH(u/v/w) are gate-driven by the insulated gate drivers 1H(u/v/w), respectively. Also, the high-side switching devices SWH(u/v/w) are connected to between the power-system power supply end (application end of first motor drive voltage VD1) and individual-phase input ends of the motor M, respectively.

The low-side switching devices SWL(u/v/w) are gate-driven by the insulated gate drivers 1L(u/v/w), respectively. Also, the low-side switching devices SWL(u/v/w) are connected to between the individual-phase input ends of the motor M and the power-system grounding end (application end of second motor drive voltage VD2), respectively.

In addition, although IGBTs are used as high-side switching devices SWH(u/v/w) and low-side switching devices SWL(u/v/w) in this figure, yet it is also allowable to use SiC-MOSFETs or Si-MOSFETs instead of IGBTs as described before.

The ECU 2 drives the high-side switching devices SWH(u/v/w) and the low-side switching devices SWL(u/v/w) via the insulated gate drivers 1H(u/v/w) and 1L(u/v/w), respectively, so as to control the rotational drive of the motor M. The ECU 2 is also equipped with a function of fulfilling various types of safety control by monitoring FLT1 terminals and FLT2 terminals of the insulated gate drivers 1H(u/v/w) and 1L(u/v/w), respectively.

The smoothing capacitor 600 is provided to smooth a voltage between the first motor drive voltage VD1 and the application end of the second motor drive voltage VD2. The smoothing capacitor 600 stabilizes a DC voltage (=a voltage between the first motor drive voltage VD1 and the application end of the second motor drive voltage VD2) that varies in response to variations of power consumption of the motor M.

In this connection, the foregoing signal transmission device 200X may preferably be used as each of the insulated gate drivers 1H(u/v/w) and 1L(u/v/w). For example, the insulated gate driver 1H and the insulated gate driver 1L of one phase (e.g., U-phase according to this figure) out of the three phases may be given by the foregoing signal transmission device 200X.

In addition, when the foregoing signal transmission device 200X is used as the insulated gate driver 1H(u/v/w), the switch SW of FIG. 10 serves as the high-side switch SWH(u/v/w) of FIG. 14. In this case, the node n1 shown in FIG. 10 can be designated as an application end of the first motor drive voltage VD1 of FIG. 14. Also, the node n2 shown in FIG. 10 can be designated as a connection end with the motor M of FIG. 14.

Also, when the foregoing signal transmission device 200X is used as the insulated gate driver 1L(u/v/w), the switch SW of FIG. 10 serves as the low-side switch SWL(u/v/w) of FIG. 14. In this case, the node n1 shown in FIG. 10 can be designated as a connection end with the motor M of FIG. 14. Also, the node n2 shown in FIG. 10 can be designated as an application end of the second motor drive voltage VD2 of FIG. 14.

### Modifications

Otherwise, the present disclosure is not limited to the above-described embodiment and may be changed or modified in various ways without departing from the gist of the invention. For example, although insulated gate bipolar transistors (IGBTs) are used as the switching device SW, the high-side switching devices SWH(u/v/w), and the low-side switching devices SWL(u/v/w), respectively, in the above-described implemental example, yet the configuration of the half-bridge output stage is not limited to this, and MOS field-effect transistors using SiC semiconductor or MOS field-effect transistors using Si semiconductor may instead be adopted.

Furthermore, whereas the high-impedance signal detection circuit 427 has been described as monitoring the output V1 of the second reception circuit 422 to detect the specific period, the high-impedance signal detection circuit 427 may instead be configured so as to monitor the output of the first reception circuit 421 to detect the specific period. In this case, it is appropriate to monitor the first internal signal S1 with an embodiment equivalent to the above-described monitoring embodiment of the second internal signal S2.

### Appendices

A signal transmission device (200X) disclosed herein includes: a transmission circuit (410) configured to output a first internal signal (S1) and a second internal signal (S2), which are pulse-driven, in response to an input signal (IN); a reception circuit (420) configured to output a first control signal (S3) in response to the first internal signal (S1) and the second internal signal (S2); an insulation circuit (430) configured to transmit the first internal signal (S1) and the second internal signal (S2) while keeping isolation between the transmission circuit (410) and the reception circuit (420); and a drive circuit (423,501) configured to drive a driving-targeted switching device (SW) in response to the first control signal (S3), wherein the transmission circuit (410) drives at least one of the first internal signal (S1) and the second internal signal (S2) at a specific period different from that of the input signal (IN) in response to an external signal (ASC) different from the input signal (IN), the reception circuit (420), upon detecting that the period of at least one of the first internal signal (S1) and the second internal signal (S2) equals the specific period, outputs a second control signal (S5) different from the first control signal (S3), and the drive circuit (423,501), upon receiving the second control signal (S5), sets an output node (OUT) of the drive circuit (423,501) to a high-impedance state (first configuration).

Preferably, in the signal transmission device (200X) according to the first configuration, the drive circuit (423,501): includes a plurality of output switching devices (P1, N1) connected to the output node (OUT) and configured to generate the drive control signal (Ga) for driving the drive-targeted switching device; through switching operations of the individual output switching devices (P1, N1), outputs the drive control signal (Ga) to drive the drive-targeted switching device (SW); and turns off all the output switching devices (P1, N1) to halt the switching operations and set the output node (OUT) to the high-impedance state (second configuration).

Preferably, in the signal transmission device (200X) according to the first configuration or the second configuration, the transmission circuit (410) drives, at the specific period, the first internal signal (S1) in response to the external signal (ASC), and the reception circuit (420), upon detecting that the first internal signal (S1) has a period equal to the specific period, sets the output node (OUT) to the high-impedance state (third configuration).

Preferably, in the signal transmission device (200X) according to any one of the first to third configurations, the reception circuit (420) includes: a timer circuit configured to generate a timer drive signal (S6) switchably between a first logic level and a second logic level in response to the first internal signal (S1), where the timer drive signal (S6) is set to the first logic level at a first timing, which is at least one of a rising edge and a falling edge of the first internal signal (S1), while the timer drive signal (S6) is switched to the second logic level on condition that a first set time (T1) has elapsed after the first timing and before incoming of the succeeding first timing; a detection signal generation circuit (427) configured to generate a detection signal (S5) switchably between a third logic level and a fourth logic level in response to the timer drive signal (S6), where the detection signal (S5) is set to the third logic level on condition that a continued time of the timer drive signal (S6) held at the first logic level is less than a second set time (T2), while the detection signal (S5) is set to the fourth logic level on condition that the continued time is not less than the second set time (T2); and a drive switching circuit (423) which is so configured that when the detection signal (S5) is at the third logic level, the drive-targeted switching device (SW) is driven, and when the detection signal (S5) is at the fourth logic level, drive of the drive-targeted switching device (SW) is halted, followed by setting of the output node (OUT) to the high-impedance state, and the first set time (T1) is shorter than a period of the input signal (IN) and longer than the specific period (fourth configuration).

Preferably, in the signal transmission device (200X) according to the first configuration, the detection signal generation circuit (427) includes: a reset circuit configured to output a reset signal (RSTH) when the timer drive signal (S6) is at the second logic level; an oscillator circuit (OSC) configured to output a clock signal (CLKH); and a counter circuit (506) configured to count number of clocks of the clock signal (CLKH) to acquire a count value, where upon receiving the reset signal (RSTH), the count value is reset to a value of zero so that the continued time is measured based on the count value (fifth configuration).

Preferably, the signal transmission device (200X) according to any one of the first to fifth configurations further includes: a first chip (410) on which circuit components of the transmission circuit (410) are integrated; a second chip (420) on which circuit components of the reception circuit (420) and the drive circuit (423,501) are integrated; and a third chip (430) on which circuit components of the insulation circuit (430) are integrated, these chips being sealed in a singular package (sixth configuration).

Preferably, in the signal transmission device (200X) according to the sixth configuration, the first chip (410) includes: a first input terminal configured to receive the input signal (IN) as an external input; and a second input terminal (ASC) configured to receive the external signal (ASC) as an external input (seventh configuration).

An electronic device (400) disclosed herein includes: a plurality of the drive-targeted switching devices (SW) being power transistors, respectively; a plurality of gate driver ICs configured to drive individual gates of the plurality of drive-targeted switching devices (SW), respectively; and an external driver circuit (700) so configured that signal input is given to the output node (OUT) of a high-impedance state to drive the drive-targeted switching devices (SW), wherein at least one of the plurality of gate driver ICs is the signal transmission device (200X) according to any one of the first to seventh configurations (eighth configuration).

A vehicle (450) disclosed herein includes the electronic device (400) according to the eighth configuration (ninth configuration).

According to the signal transmission device (200X) of the first configuration, the output node (OUT) of the driving circuit (423,501) can be arbitrarily set to a high-impedance state. Therefore, it becomes possible, for example, to drive drive-targeted switching devices (SW) by using the external input (IN) under a halted state of the signal transmission device (200X).

According to the signal transmission device (200X) of the second configuration, the output node (OUT) can preferably be set to the high-impedance state.

According to the signal transmission device (200X) of the third configuration, the output node (OUT) can more preferably be set to a high-impedance state.

According to the signal transmission device (200X) of the fourth configuration, the specific period can preferably be detected.

According to the signal transmission device (200X) of the fifth configuration, the specific period can more preferably be detected.

According to the signal transmission device (200X) of the sixth configuration, upsizing of the chips constituting the signal transmission device (200X) can be suppressed.

According to the signal transmission device (200X) of the seventh configuration, it becomes possible to drive the driving circuit (423,501) or set the output node (OUT) to a high-impedance state depending on the signal received from the first chip (410) as an external input.

According to the electronic device (400) of the eighth configuration, setting the output node (OUT) to a high-impedance state allows the drive-targeted switching devices (SW) to be driven by the external driver circuit (700). As a result, it becomes possible to drive-control the drive-targeted switching devices (SW) even with operation of the signal transmission device (200X) halted.

According to the electronic device (400) of the ninth configuration, there can be provided a vehicle (450) in which the drive-targeted switching devices (SW) without depending on the (200X). Thus, even with operation of the signal transmission device (200X) halted, it becomes possible to drive the drive-targeted switching devices (SW).

### REFERENCE SIGNS LIST

5 semiconductor device
11, 11A-11F low-potential terminal
12, 12A-12F high-potential terminal
21, 21A-21D transformer
22 low-potential coil (primary coil)
23 high-potential coil (secondary coil)
24 first inner end
25 first outer end
26 first spiral portion
27 second inner end
28 second outer end
29 second spiral portion
31 first low-potential wiring
32 second low-potential wiring
33 first high-potential wiring
34 second high-potential wiring
41 semiconductor chip
42 first principal surface
43 second principal surface
44A-44D chip side wall
45 first functional device
51 insulation layer
52 insulation principal surface
53A-53D insulation side wall
55 bottom insulation layer
56 top insulation layer
57 interlayer insulation layer
58 first insulation layer
59 second insulation layer
60 second functional device
61 sealing conductor
62 device region
63 outer region
64 sealing plug conductor
65 sealing via conductor
66 first inner region
67 second inner region
71 through wiring
72 low-potential connection wiring
73 lead wiring
74 first connection plug electrode
75 second connection plug electrode
76 pad plug electrode
77 substrate plug electrode
78 first electrode layer
79 second electrode layer
80 wiring plug electrode
81 high-potential connection wiring
82 pad plug electrode
85 dummy pattern
86 high-potential dummy pattern
87 first high-potential dummy pattern
88 second high-potential dummy pattern
89 first region
90 second region
91 third region
92 first connection part
93 first pattern
94 second pattern
95 third pattern
96 first outer circumferential line
97 second outer circumferential line
98 first middle line
99 first connection line
100 slit
130 separation structure
140 inorganic insulation layer
141 first inorganic insulation layer
142 second inorganic insulation layer
143 low-potential pad opening
144 high-potential pad opening
145 organic insulation layer
146 first part
147 second part
148 low-potential terminal opening
149 high-potential terminal opening
200 signal transmission device
200p primary circuit system
200s secondary circuit system
210 controller chip (first chip)
211 pulse transmission circuit (pulse generator)
212, 213 buffer
220 driver chip (second chip)
221, 222 buffer
223 pulse reception circuit (RS flip-flop)
224 driver
230 transformer chip (third chip)
230a first wiring layer (lower layer)
230b second wiring layer (upper layer)
231, 232 transformer
231p, 232p primary coil
231s, 232s secondary coil
300 transformer chip
301 first transformer
302 second transformer
303 third transformer
304 fourth transformer
305 first guard ring
306 second guard ring
a1-a8 pad (corresponding to first current feed pad)
b1-b8 pad (corresponding to first voltage measurement pad)
c1-c4 pad (corresponding to second current feed pad)
d1-d4 pad (corresponding to second voltage measurement pad)
e1, e2 pad
L1p, L2p primary coil
L1s, L2s, L3s, L4s secondary coil
T21, T22, T23, T24, T25, T26 external terminal
X first direction
X21, X22, X23 internal terminal
Y second direction
Y21, Y22, Y23 wiring
Z normal direction
Z21, Z22, Z23 via
400 electronic device
410 first semiconductor chip
411 first transmission circuit
412 second transmission circuit
415 logic circuit
420 second semiconductor chip
421 first reception circuit
422 second reception circuit
423 driver circuit
425 logic circuit
427 high-impedance signal detection circuit
430 third semiconductor chip
431 first transformer
432 second transformer
433 third transformer
434 fourth transformer
435 fifth transformer
436 sixth transformer
450 vehicle
501 output circuit
503 timer circuit
504 AND gate
505 UVLO circuit
506 counter circuit
600 smoothing capacitor
700 external driver circuit
ASC high-impedance input signal
CLKHclock signal
D1, D2 diode
DFF1-DFF4 D flip-flop
E1 voltage source
E2 voltage source
Ga, Gbdrive control signal
Gc, Gddrive signal
IN input signal
INV1 inverter
M motor
OSC oscillator
OUT output signal
P1, N1transistor
R1, R2 resistor
RSTH reset signal
S set signal
S1 first internal signal
S2 second internal signal
S3 driver control signal
S5 high-impedance control signal
S6 timer drive signal
S7 output signal
SW switching device
SW switch
T1 first set time
T2 second set time
V1output
VCC1 supply voltage
VCC2 supply voltage
Vge gate signal

1. A signal transmission device comprising:
a transmission circuit configured to output a first internal signal and a second internal signal, which are pulse-driven, in response to an input signal;
a reception circuit configured to output a first control signal in response to the first internal signal and the second internal signal;
an insulation circuit configured to transmit the first internal signal and the second internal signal while keeping isolation between the transmission circuit and the reception circuit; and
a drive circuit configured to drive a driving-targeted switching device in response to the first control signal, wherein
the transmission circuit drives at least one of the first internal signal and the second internal signal at a specific period different from that of the input signal in response to an external signal different from the input signal,
the reception circuit, upon detecting that the period of at least one of the first internal signal and the second internal signal equals the specific period, outputs a second control signal different from the first control signal, and
the drive circuit, upon receiving the second control signal, sets an output node of the drive circuit to a high-impedance state.

2. The signal transmission device as claimed in claim 1, wherein
the drive circuit:
includes a plurality of output switching devices connected to the output node and configured to generate the drive control signal for driving the drive-targeted switching device;
through switching operations of the individual output switching devices, outputs the drive control signal to drive the drive-targeted switching device; and
turns off all the output switching devices to halt the switching operations and set the output node to the high-impedance state.

3. The signal transmission device as claimed in claim 1, wherein
the transmission circuit drives, at the specific period, the first internal signal in response to the external signal, and
the reception circuit, upon detecting that the first internal signal has a period equal to the specific period, sets the output node to the high-impedance state.

4. The signal transmission device as claimed in claim 1, wherein
the reception circuit includes:
a timer circuit configured to generate a timer drive signal switchably between a first logic level and a second logic level in response to the first internal signal, where the timer drive signal is set to the first logic level at a first timing, which is at least one of a rising edge and a falling edge of the first internal signal, while the timer drive signal is switched to the second logic level on condition that a first set time has elapsed after the first timing and before incoming of the succeeding first timing;
a detection signal generation circuit configured to generate a detection signal switchably between a third logic level and a fourth logic level in response to the timer drive signal, where the detection signal is set to the third logic level on condition that a continued time of the timer drive signal held at the first logic level is less than a second set time, while the detection signal is set to the fourth logic level on condition that the continued time is not less than the second set time; and
a drive switching circuit which is so configured that when the detection signal is at the third logic level, the drive-targeted switching device is driven, and when the detection signal is at the fourth logic level, drive of the drive-targeted switching device is halted, followed by setting of the output node to the high-impedance state, and
the first set time is shorter than a period of the input signal and longer than the specific period.

5. The signal transmission device as claimed in claim 4, wherein
the detection signal generation circuit includes:
a reset circuit configured to output a reset signal when the timer drive signal is at the second logic level;
an oscillator circuit configured to output a clock signal; and
a counter circuit configured to count number of clocks of the clock signal to acquire a count value, where upon receiving the reset signal, the count value is reset to a value of zero so that the continued time is measured based on the count value.

6. The signal transmission device as claimed in claims 1, further comprising:
a first chip on which circuit components of the transmission circuit are integrated;
a second chip on which circuit components of the reception circuit and the drive circuit are integrated; and
a third chip on which circuit components of the insulation circuit are integrated,
these chips being sealed in a singular package.

7. The signal transmission device as claimed in claim 6, wherein
the first chip includes:
a first input terminal configured to receive the input signal as an external input; and
a second input terminal configured to receive the external signal as an external input.

8. An electronic device comprising:
a plurality of the drive-targeted switching devices being power transistors, respectively;
a plurality of gate driver ICs configured to drive individual gates of the plurality of drive-targeted switching devices, respectively; and
an external driver circuit so configured that signal input is given to the output node of a high-impedance state to drive the drive-targeted switching devices, wherein at least one of the plurality of gate driver ICs is the signal transmission device as claimed in claim 1.

9. A vehicle comprising the electronic device as claimed in claim 8.
